(19) United States
(12) Patent Application Publication
(10) Pub. No.: US 2007/0052095 A1
(43) Pub. Date: Mar. 8, 2007

(54) Semiconductor device and manufacturing method thereof

(76) Inventors: Katsuhiro Torii, Tokyo (JP); Shuji Matsuo, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/514,873

(22) Filed: Sep. 5, 2006

(30) Foreign Application Priority Data
Sep. 6, 2005 (JP) 2005-258091

(51) Int. Cl. H01L 23/48; H01L 21/4763

(52) U.S. Cl. 257/737; 257/774; 438/629; 257/E23.145

(57) ABSTRACT

Provided is a technology capable of improving the reliability of a semiconductor device using WPP by preventing a short-circuit failure between uppermost-level interconnects. In the present invention, a buffer layer is formed between an uppermost-level interconnect and redistribution interconnect. The uppermost-level interconnect is made of a copper film, while the buffer layer is made of an aluminum film. The redistribution interconnect is made of a film stack of a copper film and a nickel film. In such a semiconductor device, stress concentration occurs at a triple point when temperature cycling between low temperature and high temperature is performed. The stress concentration on the triple point is relaxed by the presence of the buffer layer, whereby the conduction of the stress to an interface just below the triple point can be suppressed. Peeling due to the stress at the interface can thus be prevented.

### CROSS-REFERENCE TO RELATED APPLICATION

The present application claims priority from Japanese patent application No. 2005-258091 filed on Sep. 6, 2005, the content of which is hereby incorporated by reference into this application.

### BACKGROUND OF THE INVENTION

The present invention relates to a semiconductor device and a manufacturing technology thereof, in particular, to a technology effective when applied to a semiconductor device using wafer process package (WPP) and a manufacturing technology thereof.

Examples of the conventionally known technologies include a technology of forming a via made of an aluminum film over a lower-level copper interconnect and then forming an upper-level copper interconnect through the via (refer to, for example, Japanese Unexamined Patent Publication No. Hei 11(1999)-121615); a technology of forming an upper-level interconnect made of a film stack of a chromium film and a copper film over an aluminum interconnect through a polyimide film (refer to, for example, Japanese Unexamined Patent Publication No. 2003-234348); a technology of forming an upper-level interconnect made of a film stack of a chromium film and a copper film over an aluminum pad through a polyimide film and then coating the upper-level interconnect with nickel (refer to, for example, Japanese Unexamined Patent Publication No. 2003-234429); a technology of forming a via for connecting a lower-level copper interconnect to an upper-level copper interconnect by using a material (such as Ti, Zr, Ta, Sn or Mg) which can be dispersed easily in copper (refer to, for example, Japanese Unexamined Patent Publication No. Hei 11(1999)-204644), and a technology of connecting an upper-level copper interconnect to a lower-level interconnect by a via made of a copper film (refer to, for example, Japanese Unexamined Patent Publication No. 2004-165234).

### SUMMARY OF THE INVENTION

A technology of integrating a package process (latter step) and a wafer process (former step) and finishing packaging while in the wafer stage, which is a so-called wafer process package (WPP), is a technology of applying a wafer process even to the packaging. This WPP technology is advantageous because it needs far fewer steps than the conventional method in which package process is performed for each of semiconductor chips cut out from a semiconductor wafer.

When WPP is adopted, a semiconductor device is manufactured by the following steps. First, semiconductor elements such as MISFET (Metal Insulator Semiconductor Field Effect Transistor) are formed over the main surface of a semiconductor wafer, followed by the formation of a plurality of interconnect layers over the semiconductor elements. These interconnect layers are, for example, made of a copper film and can be formed by forming a trench in an interlayer insulating film and then filling a conductor film in the trench. Over the uppermost-level interconnect formed at the uppermost layer of the interconnect layers, a film stack made of a silicon nitride film and a silicon oxide film is formed, whereby the silicon nitride film and the silicon oxide film are formed over the uppermost-level interconnect made of a copper film and the interlayer insulating film having the uppermost-level interconnect buried in the trench.

After formation of a polyimide resin film over the silicon oxide film, the silicon nitride film, silicon oxide film and polyimide resin film are patterned to form an opening portion having a bottom surface from which the uppermost-level interconnect is exposed.

A thin electrode layer (seed layer) is formed over the polyimide resin film including the inside of the opening portion and a redistribution interconnect is formed over the electrode layer by using the plating process. The redistribution interconnect is made of, for example, a film stack of a copper film and a nickel film. After formation of a polyimide resin film over the redistribution interconnect, patterning is conducted to expose an end portion of the redistribution interconnect. A bump electrode is then formed over the exposed one end portion of the redistribution interconnect. In such a manner, the redistribution interconnect and the bump electrode connected thereto are formed while the semiconductor wafer is intact.

In high-speed SRAM (Static Random Access Memory) or CMOS (Complementary Metal Oxide Semiconductor) logic products, for example, the above-described WPP is employed for the purpose of a reduction in package cost and speed up and they have a package structure so as to permit flip chip connection to a mounting substrate via a bump electrode made of a solder. The WPP used in such semiconductor devices employs a structure as illustrated in FIG. 1. FIG. 1 is a cross-sectional view of the structure of WPP. As illustrated in FIG. 1, an uppermost-level interconnect 1 made of a copper film is filled in a trench of an interlayer insulating film 2 and a film stack made of a silicon nitride film 3 and a silicon oxide film 4 is formed over the interlayer insulating film 2 including the upper surface of the uppermost-level interconnect 1. A polyimide resin film 5 is formed over the silicon oxide film 4. The silicon nitride film 3, silicon oxide film 4 and polyimide resin film 5 have an opening portion 6 formed therein. The bottom of the opening portion 6 reaches the uppermost-level interconnect 1 and a redistribution interconnect 7 is formed so as to fill this opening 6 therewith. This redistribution interconnect 7 is made of a film stack of, for example, a copper film 8 and a nickel film 9. A polyimide resin film 10 is formed over the redistribution interconnect 7 and a bump electrode 12 is formed in an opening portion 11 formed in the polyimide resin film 10.

Similar to ordinary products, a semiconductor device having such a structure is subjected to a reliability test (selection test) in which it is operated repeatedly under temperature cycling between −50° C. to 125° C. Repeated applications of a thermal load to the semiconductor device cause expansion and contraction of films constituting the semiconductor device. In particular, a contraction stress occurs in the nickel film 9 and polyimide resin film 5, which are portions of the redistribution interconnect 7, owing to the influence of the temperature cycling in the reliability test. As illustrated in FIG. 2 which is an enlarged view of a region of FIG. 1 surrounded in a square, there occurs stress concentration on a triple point at which interfaces of three films, that is, the copper film 8 constituting the redistribution interconnect 7, the polyimide resin film 5 and the silicon oxide film 4, are brought into contact with each other. Then, interfacial peeling occurs at a site where the adhesive force of films is the lowest in the vicinity of a stress concentration region, that is, at the interface between the interlayer insulating film 2 and the silicon nitride film 3. In other words, interfacial peeling occurs between the interlayer insulating film 2, which exists between a plurality of uppermost-level interconnects 1, and the silicon nitride film 3 formed as a diffusion preventive film of the uppermost-level interconnects 1.

The reliability test is followed by an electrical characteristics test. In this test, a voltage is applied to the uppermost-level interconnect 1. When a voltage is applied, copper constituting the uppermost-level interconnect 1 starts drifting in the peeled portion which has appeared at the interface of the interlayer insulating film 2 and the silicon nitride film 3 and causes conduction between two adjacent uppermost-level interconnects 1. This leads to occurrence of a short-circuit fault. Such a phenomenon is not a problem in aluminum interconnection, while it becomes a problem in copper (Cu) interconnection because copper moves very easily by an electric field.

An object of the present invention is to provide a technology capable of improving the reliability of a semiconductor device using WPP by preventing a short-circuit fault between uppermost-level interconnects.

The above-described and the other objects and novel features of the present invention will be apparent by the description herein and accompanying drawings.

Outline of typical inventions, of the inventions disclosed by the present application, will next be described briefly.

In one aspect of the present invention, there is thus provided a semiconductor device comprising (a) a semiconductor substrate, (b) an interlayer insulating film formed over the semiconductor substrate, (c) an uppermost-level interconnect formed so as to bury it in the interlayer insulating film, (d) a buffer layer formed over the uppermost-level interconnect, (e) a redistribution interconnect formed over the buffer layer, and (f) a bump electrode formed over one end portion of the redistribution interconnect.

In another aspect of the present invention, there is also provided a manufacturing method of a semiconductor device, which comprises the steps of: (a) forming an interlayer insulating film over a semiconductor substrate, (b) forming an uppermost-level interconnect so as to bury it in the interlayer insulating film, (c) forming a first insulating film over the interlayer insulating film having the uppermost-level interconnect buried therein, (d) forming a first opening portion in the first insulating film to expose the uppermost-level interconnect from the first opening portion, (e) forming a first conductor film over the first insulating film including the inside of the first opening portion, (f) patterning the first conductor film to form a buffer layer, (g) forming a second insulating film over the buffer layer, (h) forming a second opening portion in the second insulating film to expose the buffer layer from the second opening portion, (i) forming a second conductor film over the second insulating film including the inside of the second opening portion, and (j) patterning the second conductor film to form a redistribution interconnect.

Advantages available by the typical inventions, among the inventions disclosed by the present application, will next be described briefly.

The present invention makes it possible to improve the reliability of a semiconductor device using WPP by reducing short-circuit faults between uppermost-level interconnects caused by heating cycle.

### BRIEF DESCRIPTION OF THE DRAWINGS

FIG. 1 is a cross-sectional view illustrating a portion of a semiconductor device investigated by the present inventors;

FIG. 2 is a partially enlarged view of FIG. 1;

FIG. 3 is a cross-sectional view illustrating a portion of a semiconductor device according to Embodiment 1 of the present invention;

FIG. 4 is a cross-sectional view illustrating a portion of the semiconductor device according to Embodiment 1;

FIG. 5 is a cross-sectional view illustrating a manufacturing step of the semiconductor device according to Embodiment 1;

FIG. 6 is a cross-sectional view illustrating a manufacturing step of the semiconductor device following that of FIG. 5;

FIG. 7 is a cross-sectional view illustrating a manufacturing step of the semiconductor device following that of FIG. 6;

FIG. 8 is a cross-sectional view illustrating a manufacturing step of the semiconductor device following that of FIG. 7;

FIG. 9 is a cross-sectional view illustrating a manufacturing step of the semiconductor device following that of FIG. 8;

FIG. 10 is a cross-sectional view illustrating a manufacturing step of the semiconductor device following that of FIG. 9;

FIG. 11 is a cross-sectional view illustrating a manufacturing step of the semiconductor device following that of FIG. 10;

FIG. 12 is a cross-sectional view illustrating a manufacturing step of the semiconductor device following that of FIG. 11;

FIG. 13 is a cross-sectional view illustrating a manufacturing step of the semiconductor device following that of FIG. 12;

FIG. 14 is a cross-sectional view illustrating a manufacturing step of the semiconductor device following that of FIG. 13;

FIG. 15 is a cross-sectional view illustrating a manufacturing step of the semiconductor device following that of FIG. 14;

FIG. 16 is a cross-sectional view illustrating a manufacturing step of the semiconductor device following that of FIG. 15;

FIG. 17 is a cross-sectional view illustrating a manufacturing step of the semiconductor device following that of FIG. 16;

FIG. 18 is a cross-sectional view illustrating a manufacturing step of the semiconductor device following that of FIG. 17;

FIG. 19 is a cross-sectional view illustrating a modification example of Embodiment 1;

FIG. 20 is a cross-sectional view illustrating a semiconductor device according to Embodiment 2;

FIG. 21 is a cross-sectional view illustrating a manufacturing step of the semiconductor device according to Embodiment 2;

FIG. 22 is a cross-sectional view illustrating a manufacturing step of the semiconductor device following that of FIG. 21;

FIG. 23 is a cross-sectional view illustrating a manufacturing step of the semiconductor device following that of FIG. 22;

FIG. 24 is a cross-sectional view illustrating a manufacturing step of the semiconductor device following that of FIG. 23; and

FIG. 25 is a cross-sectional view illustrating a manufacturing step of the semiconductor device following that of FIG. 24.

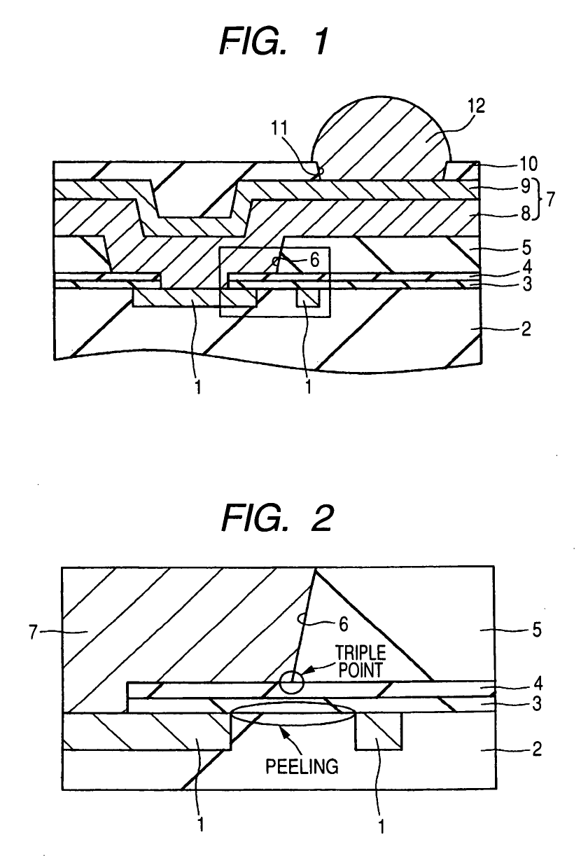

### DETAILED DESCRIPTION OF THE INVENTION

In the below-described embodiments, a description will be made after divided in plural sections or in plural embodiments if necessary for convenience's sake. These plural sections or embodiments are not independent each other, but in a relation such that one is a modification example, details or complementary description of a part or whole of the other one unless otherwise specifically indicated.

In the below-described embodiments, when a reference is made to the number of elements (including the number, value, amount and range), the number of elements is not limited to a specific number but can be greater than or less than the specific number unless otherwise specifically indicated or in the case it is principally apparent that the number is limited to the specific number.

Moreover in the below-described embodiments, it is needless to say that the constituting elements (including element steps) are not always essential unless otherwise specifically indicated or in the case where it is principally apparent that they are essential.

Similarly, in the below-described embodiments, when a reference is made to the shape or positional relationship of the constituting elements, that substantially analogous or similar to it is also embraced unless otherwise specifically indicated or in the case where it is utterly different in principle. This also applies to the above-described value and range.

Embodiments of the present invention will hereinafter be described specifically based on accompanying drawings. In all the drawings for describing the below-described embodiments, elements having like function will be identified by like reference numerals and overlapping descriptions will be omitted.

### Embodiment 1

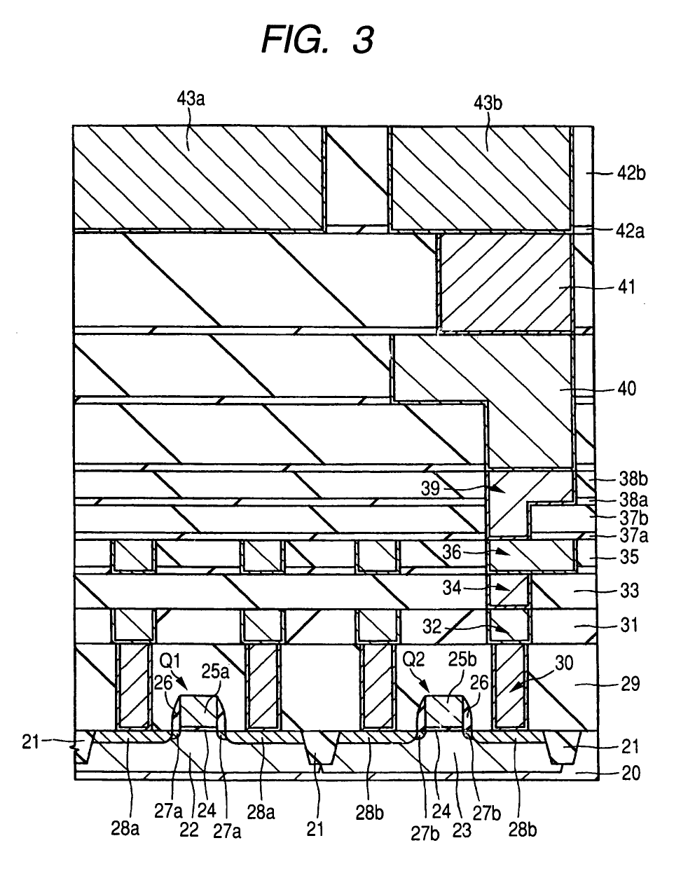

FIG. 3 is a cross-sectional view of a semiconductor device according to Embodiment 1 in which its structure including interconnects is illustrated. The semiconductor device of FIG. 3 has, for example, an MISFET constituting a high-speed SRAM or logic circuit formed therein. Over the main surface of a semiconductor substrate 20 made of, for example, silicon single crystal, an element isolation region 21 having, for example, an STI (Shallow Trench Isolation) structure is formed. Active regions are separated by the element isolation region 21. Of the active regions, a p well 22 is formed in a formation region of an n channel MISFET Q1, while an n well 23 is formed in a formation region of a p channel MISFET Q2. The p well 22 is a semiconductor region in which a p type impurity such as boron (B) has been introduced, while the n well 23 is another semiconductor region in which an n type impurity such as phosphorus (P) or arsenic (As) has been introduced.

The n channel MISFET Q1 is formed over the p well 22. This n channel MISFET Q1 has the following structure. Described specifically, a gate insulating film 24 is formed over the p well 22. Over the gate insulating film 24, a gate electrode 25a is formed. The gate insulating film 24 is made of, for example, a silicon oxide film but may be made of a film having a higher dielectric constant than that of the silicon oxide film. The gate electrode 25a is made of, for example, a polysilicon film. For example, an n type impurity has been introduced into this polysilicon film in order to reduce the threshold voltage of the n channel MISFET Q1.

Sidewalls 26 are formed over the side walls on both sides of the gate electrode 25a. In the p well 22 below these sidewalls 26, a low-concentration n type impurity diffusion region 27a is formed. Outside this low-concentration n-type impurity diffusion region 27a, a high-concentration n-type impurity diffusion region 28a is formed. The low-concentration n-type impurity diffusion region 27a and high-concentration n-type impurity diffusion region 28a are semiconductor regions having an n type impurity introduced therein. An n type impurity has been introduced at a higher concentration into the high-concentration n-type impurity diffusion region 28a than into the low-concentration n-type impurity diffusion region 27a. By these low-concentration n-type impurity diffusion region 27a and high-concentration n-type impurity diffusion region 28a, a source region or a drain region of the n channel MISFET Q1 is formed. A so-called LDD (Lightly Doped Drain) structure is formed by constituting the source region or drain region from the low-concentration n-type impurity diffusion region 27a and high-concentration n-type impurity diffusion region 28a. This enables to relax the electric field concentration below the gate electrode 25a.

Over the n well 23, the p channel MISFET Q2 is formed. This p channel MISFET Q2 has almost a similar constitution to that of the n channel MISFET Q1. Described specifically, a gate insulating film 24 is formed over an n well 23 and a gate electrode 25b is formed over this gate insulating film 24. The gate electrode 25b is made of, for example, a polysilicon film and has a p type impurity introduced therein. The threshold voltage of the p channel MISFET Q2 can be reduced by introducing the p type impurity into the gate electrode 25b. In this Embodiment 1, an n type impurity is introduced into the gate electrode 25a of the n channel MISFET Q1, while a p type impurity is introduced into the gate electrode 25b of the p channel MISFET Q2. This enables reduction in the threshold voltage in both the n channel MISFET Q1 and p channel MISFET Q2.

Sidewalls 26 are formed over the side walls on both sides of the gate electrode 25b. In the n well 23 below the sidewalls 26, a low-concentration p type impurity diffusion region 27b is formed. Outside this low-concentration p-type impurity diffusion region 27b, a high-concentration p-type impurity diffusion region 28b is formed. The low-concentration p-type impurity diffusion region 27b and high-concentration p-type impurity diffusion region 28b are semiconductor regions having a p type impurity introduced therein. A p type impurity has been introduced at a higher concentration into the high-concentration p-type impurity diffusion region 28b than into the low-concentration p-type impurity diffusion region 27b. By these low-concentration p-type impurity diffusion region 27b and high-concentration p-type impurity diffusion region 28b, a source region or drain region of the p channel MISFET Q2 is formed.

In the semiconductor device according to Embodiment 1, the n channel MISFET Q1 and p channel MISFET Q2 having the above-described respective structures are formed over the semiconductor substrate 20.

A multilevel interconnect structure of the semiconductor device according to Embodiment 1 will next be described. As illustrated in FIG. 3, the n channel MISFET Q1 and p channel MISFET Q2 formed over the semiconductor substrate 20 has thereover a silicon oxide film 29, which will be an interlayer insulating film. The silicon oxide film 29 has therein plugs 30 which reach the source region and drain region of the n channel MISFET Q1 or p channel MISFET Q2. This plug 30 is made of, for example, a film stack of a titanium nitride film, which will be a barrier metal film, and a tungsten film. Over the silicon oxide film 29 having therein the plugs 30, a silicon oxide film 31 which will be an interlayer insulating film is formed. A tungsten interconnect 32 is formed so as to bury it in this silicon oxide film 31. This tungsten interconnect 32 is electrically connected to the plug 30 formed in the underlying layer. Over the tungsten interconnect 32, a silicon oxide film 33 is formed. A plug 34 is formed so as to bury it in the silicon oxide film 33. This plug 34 is, similar to the plug 30, made of a film stack of a barrier metal film and a tungsten film. The plug 34 is electrically connected to the tungsten interconnect 32 formed therebelow.

Over the silicon oxide film 33 having the plug 34 formed therein, a silicon oxide film 35 which will be an interlayer insulating film is formed and a first copper interconnect 36 is formed so as to bury it in the silicon oxide film 35. This first copper interconnect 36 is made of a film stack of a barrier metal film for preventing the diffusion of copper and a copper film. Over the first copper interconnect 36, a silicon nitride film 37a is formed to prevent diffusion of copper. Over this silicon nitride film 37a, a silicon oxide film 37b is formed. Over the silicon oxide film 37b, a silicon nitride film 38a and a silicon oxide film 38b are stacked one after another. A second copper interconnect 39 is formed so as to bury it in the silicon nitride film 38a and silicon oxide film 38b. This second copper interconnect 39 is electrically connected to the first copper interconnect 36 formed therebelow. A third copper interconnect 40 and plug 41 are formed over the second copper interconnect 39 in a similar manner. The third copper interconnect 40 and plug 41 are also made of a film stack of a barrier metal film and a copper film. Over the interlayer insulating film having the plug 41 formed therein, an interlayer insulating film made of a silicon nitride film 42a and a silicon oxide film 42b is formed. Uppermost-level interconnects (pads) 43a and 43b are formed so as to bury them in the interlayer insulating film. Similar to the other copper interconnects, the uppermost-level interconnects 43a and 43b are made of a film stack of a barrier metal film and a copper film.

In Embodiment 1, as described above, the multilevel interconnect is formed of the tungsten interconnect 32 and four copper interconnect layers. These copper interconnects can be formed using, for example, the damascene process. The multilevel interconnect has a role of electrically connecting a plurality of semiconductor elements, thereby forming a circuit. The higher-level interconnects have a greater thickness.

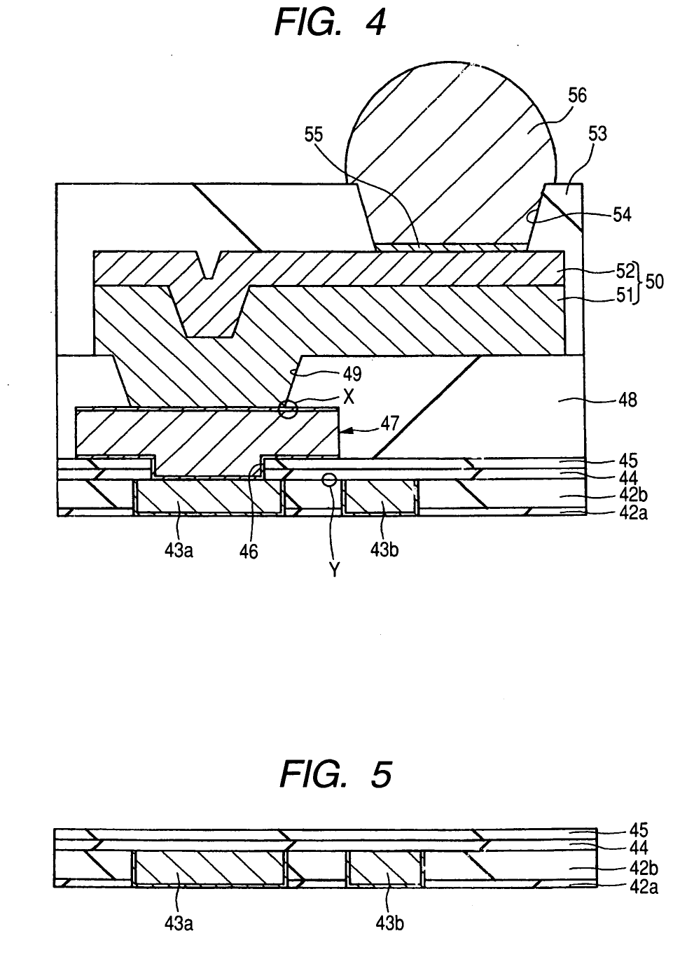

The structure over the multilevel interconnect of the semiconductor device according to Embodiment 1 will next be described referring to FIG. 4. FIG. 4 is a cross-sectional view illustrating the structure over the uppermost-level interconnects 43a and 43b illustrated in FIG. 3. In FIG. 4, a silicon nitride film 44 is formed over the silicon oxide film 42b including the uppermost-level interconnects 43a and 43b and this silicon nitride film 44 has a silicon oxide film formed thereover. In other words, a first insulating film made of the silicon nitride film 44 and silicon oxide film 45 is formed over the uppermost-level interconnects 43a and 43b. The silicon nitride film 44 has a function of preventing copper diffusion from the copper film constituting the uppermost-level interconnects 43a and 43b. The silicon nitride film 44 and silicon oxide film 45 have an opening portion (first opening portion) 46 formed therein and from the bottom of this opening portion 46, the uppermost-level interconnect 43a is exposed. A buffer layer 47 is formed so as to bury it in this opening portion 46. In other words, the buffer layer 47 is formed so as to connect to the uppermost-level interconnect 43a exposed from the opening portion 46 disposed in the silicon nitride film 44 and silicon oxide film 45. The buffer layer 47 is made of, for example, a film stack of a barrier metal film made of a titanium nitride film and an aluminum film. The buffer layer 47 may be composed of an aluminum alloy film instead of the aluminum film. Moreover, the buffer layer 47 is not limited to the aluminum film or aluminum alloy film and may be composed of another member having enough flexibility to relax a stress. As will be described later, the buffer layer 47 has a function of relaxing the stress of a redistribution interconnect and a polyimide resin film therearound. Described specifically, the buffer layer 47 is disposed for relaxing a stress caused by expansion and contraction which have generated in the redistribution interconnect and polyimide resin film therearound as a result of the reliability test in which temperature cycling between low temperature and high temperature is performed.

Over the silicon oxide film 45 including the upper surface of the buffer layer 47, a polyimide resin film (second insulating film) 48 is formed. This polyimide resin film 48 has an opening portion (second opening portion) 49 formed therein. From the bottom of this opening portion 49, the buffer layer 47 is exposed. A redistribution interconnect 50 is formed so as to bury it in this opening portion 49. In other words, the redistribution interconnect 50 is disposed so as to connect to the buffer layer 47 exposed from the opening portion 49 formed in the polyimide resin film 48. The redistribution interconnect 50 is disposed to complete the packaging while the semiconductor wafer is intact and it has a function of connecting the uppermost-level interconnect 43 to a bump electrode 56 which will be described later. In short, the redistribution interconnect 50 plays a role of a lead interconnect for connecting the uppermost-level interconnect 43a to the bump electrode 56, in other words, it has a function as an interposer for converting the space of the uppermost-level interconnect 43a to the space of the bump electrode 56.

The redistribution interconnect 50 is made of, for example, a film stack of a copper film 51 and a nickel film 52. Over this redistribution interconnect 50, a polyimide resin film (third insulating film) 53 is formed. The polyimide resin film 53 has an opening portion (third opening portion) 54 formed therein. The redistribution interconnect 50 is exposed from the bottom of the opening portion 54 and a gold film 55 is formed over this exposed redistribution interconnect 50. A bump electrode 56 made of, for example, a solder is formed over the gold film 55.

The semiconductor device of Embodiment 1 has the above-described structure. One of the characteristics of the present invention will next be described. The one of the characteristics of the present invention resides in that the buffer layer 47 is disposed over the uppermost-level interconnect 43a of the multilevel interconnect and the redistribution interconnect 50 is formed over the buffer layer 47, in short, a three-layer structure of the multilevel interconnect, buffer layer 47 and redistribution interconnect 50 is adopted.

Without the buffer layer 47, the phenomenon as described below occurs. When a semiconductor device is completed, a reliability test is conducted by checking its operation while exposing it to a drastic temperature change. At this reliability test, a stress appears as a result of expansion and contraction of films. As illustrated in FIG. 2, this stress is concentrated on the boundary of the opening portion 6 in which the redistribution interconnect 7 has been buried, more specifically, a triple point at which interfaces of films different in the expansion and contraction manners, that is, polyimide resin film 5, redistribution interconnect 7 and silicon oxide film 4 are brought into contact with each other. The resulting stress spreads to the boundary between the interlayer insulating film 2 and silicon nitride film 3 in the vicinity of this triple point and causes interfacial peeling. The reliability test is followed by the electric characteristics test. A voltage is applied to the uppermost-level interconnect 1 in this electric characteristics test. Since the interlayer insulating film 2 and the silicon nitride film 3 are peeled at their boundary between the uppermost-level interconnects 1, copper constituting the uppermost-level interconnects 1 drifts and moves between the uppermost-level interconnects 1. As a result, a short-circuit fault occurs through copper which has drifted between the uppermost-level interconnects 1.

In Embodiment 1, on the other hand, stress concentration on a triple point X as illustrated in FIG. 4 occurs. Described specifically, a stress is concentrated on a triple point at which interfaces of the redistribution interconnect 50, polyimide resin film 48 and buffer layer 47 are brought into contact with each other in the vicinity of the opening portion 49. As illustrated in FIG. 4, however, the triple point on which a stress is concentrated is separated by the buffer layer 47 from the interface Y between the silicon oxide film 42b which will be an interlayer insulating film and the silicon nitride film 44. This distance disturbs a stress concentrated on the triple point X from reaching the interface Y. In addition, the buffer layer 47 is composed mainly of, for example, a relatively soft aluminum film so that it can relax the stress concentrated on the triple point X. Thus, the buffer layer 47 thus disposed can relax the transmission of the stress to the interface Y, thereby preventing the peeling at the interface Y. In other words, peeling of the silicon nitride film 44 from the silicon oxide film (interlayer insulating film) 42b between the uppermost-level interconnect 43a and the uppermost-level interconnect 43b can be prevented, drifting of copper between the uppermost-level interconnect 43a and the uppermost-level interconnect 43b can be prevented and a short-circuit fault between the uppermost-level interconnect 43a and the uppermost-level interconnect 43b can be prevented.

Particularly when the uppermost-level interconnects 43a and 43b are made of a copper film, copper, which is more diffusible than aluminum, moves easily via a peeled portion if the peeled portion appears at the interface Y between the silicon oxide film 42b having the uppermost-level interconnects 43a and 43b buried therein and the silicon nitride film 44. Short-circuit faults due to copper drifting between the uppermost-level interconnects 43a and 43b then tend to occur. The present invention in which the buffer layer 47 is disposed to prevent the peeling at the interface Y is significantly effective when the uppermost-level interconnects 43a and 43b are made of a copper film. The present invention is however not limited to the uppermost-level interconnects 43a and 43b made of a copper film, but is also effective for the uppermost-level interconnects 43a and 43b made of an aluminum film or a tungsten film because the disposal of the buffer layer 47 can relax the stress which will otherwise cause peeling at the interface Y.

In Embodiment 1, the multilevel interconnect, buffer layer 47 and redistribution interconnect 50 are indicated separately because of the following reason. The multilevel interconnect only functions as an interconnect and a multilevel interconnect shown in FIG. 3 corresponds to it. The interconnects formed in the uppermost layer are uppermost-level interconnects (pads) 43a and 43b. The uppermost-level interconnects 43a and 43b are, among the interconnects functioning only as an interconnect, those formed in the uppermost layer.

The buffer layer 47 has, in addition to the function as an interconnect, an important function of relaxing a stress generated by the redistribution of an interconnect. This stress relaxing function is imparted to the buffer layer intentionally. Of the constituent elements of the semiconductor device of Embodiment 1, only the buffer layer 47 is imparted with a stress relaxing function intentionally. By intentionally disposing the buffer layer 47, a stress concentrated on the triple point X can be relaxed sufficiently. The buffer layer 47 is treated as an independent element in order to express this intention.

Moreover, as described above, the redistribution interconnect 50 has, in addition to a function as an interconnect, a function of completing the packaging in the stage of a semiconductor wafer. It is different in the function from a simple interconnect for the point that it converts the space of the uppermost-level interconnect 43a to the space of the bump electrode 56 and leads the uppermost-level interconnect 43a to the bump electrode 56. The redistribution interconnect 50 is therefore described separately from the multilevel interconnect. The redistribution interconnect 50 is sufficiently thicker than interconnects constituting the multilevel interconnect, which suggests that a stress generated at the redistribution interconnect 50 increases and peeling at the interface Y just below the triple point X tends to occur.

The constitution of the buffer layer 47 in Embodiment 1 will next be described. The buffer layer 47 preferably has a width greater than that of the uppermost-level interconnect 43a to which the buffer layer 47 is connected and greater than that of the opening portion 49. When the width of the buffer layer 47 is greater than that of the uppermost-level interconnect 43a, the buffer layer 47 can be laid just above the interface Y between the uppermost-level interconnect 43a and uppermost-level interconnect 43b and the transmission of a stress to the interface Y can be prevented fully. This makes it possible to prevent the peeling at the interface Y due to the stress and moreover, prevent short-circuit faults which will otherwise occur between the uppermost-level interconnects 43a and 43b. In addition, by adjusting the width of the buffer layer 47 greater than that of the opening portion 49, the buffer layer 47 can be formed just below the triple point X on which a stress is concentrated. This makes it possible to sufficiently relax the transmission of the stress from the triple point X on which a stress is concentrated to a position just below the triple point X. This also prevents the peeling at the interface Y due to stress.

A manufacturing method of a semiconductor device according to Embodiment 1 will next be described. First, an n channel MISFET Q1 and a p channel MISFET Q2 as illustrated in FIG. 3 are formed over a semiconductor substrate 2. This step is performed using the conventionally employed process technology. A multilevel interconnect is then formed over the semiconductor substrate 20. The multilevel interconnect is, as illustrated in FIG. 3, made of a tungsten interconnect 32 and four-layer copper interconnect. The copper interconnect can be formed, for example, by the damascene process. The formation of the uppermost-level interconnects 43a and 43b will next be described as an example of forming a copper interconnect by using the damascene process.

As illustrated in FIG. 5, after formation of a lower-level interconnect (not illustrated), a silicon nitride film 42a and a silicon oxide film 42b are stacked over the lower-level interconnect. The silicon nitride film 42a and silicon oxide film 42b can be formed, for example, by CVD (Chemical Vapor Deposition). A trench is then formed in an interlayer insulating film made of the silicon nitride film 42a and silicon oxide film 42b by photolithography and etching. After formation of a titanium nitride film, which will be a barrier metal film, over the silicon oxide film 42b including the inside of the trench, a seed layer made of a thin copper film is formed over the titanium nitride film. This seed layer can be formed, for example, by sputtering. A thick copper film is then formed over the silicon oxide film 42b to fill the trench with the copper film. This copper film can be formed, for example, by plating. An unnecessary portion of the copper film formed over the silicon oxide film 42b is removed by chemical mechanical polishing, whereby the uppermost-level interconnects 43a and 43b having the copper film buried in the trench can be formed. In such a manner, the uppermost-level interconnects 43a and 43b can be formed.

As illustrated in FIG. 5, a silicon nitride film 44 and a silicon oxide film 45 which will be a first insulating film are stacked over the silicon oxide film 42b including the upper surfaces of the uppermost-level interconnects 43a and 43b. The silicon nitride film 44 and silicon oxide film 45 are formed, for example, by CVD and they have a thickness of about 500 nm. The silicon nitride film 44 serves as a barrier insulating film for preventing outside dispersion of copper constituting the uppermost-level interconnects 43a and 43b. The silicon nitride film 44 may be substituted by a silicon carbonitride film.

As illustrated in FIG. 6, an opening portion (first opening portion) 46 is formed in the silicon nitride film 44 and silicon oxide film 45 by using photolithography and etching. The uppermost-level interconnect 43a is exposed from the bottom of this opening portion 46. The surface of the copper film constituting the uppermost-level interconnect 43a is exposed by this processing so that low-damage ashing or washing treatment is necessary for preventing corrosion of the exposed copper film. With regard to the shape of the opening portion 46, a structure having a low aspect ratio (a depth of the opening portion 46/diameter of the opening portion 46 ratio is about 1 or less) is preferred to facilitate the filling of a buffer layer 47 which will be described later.

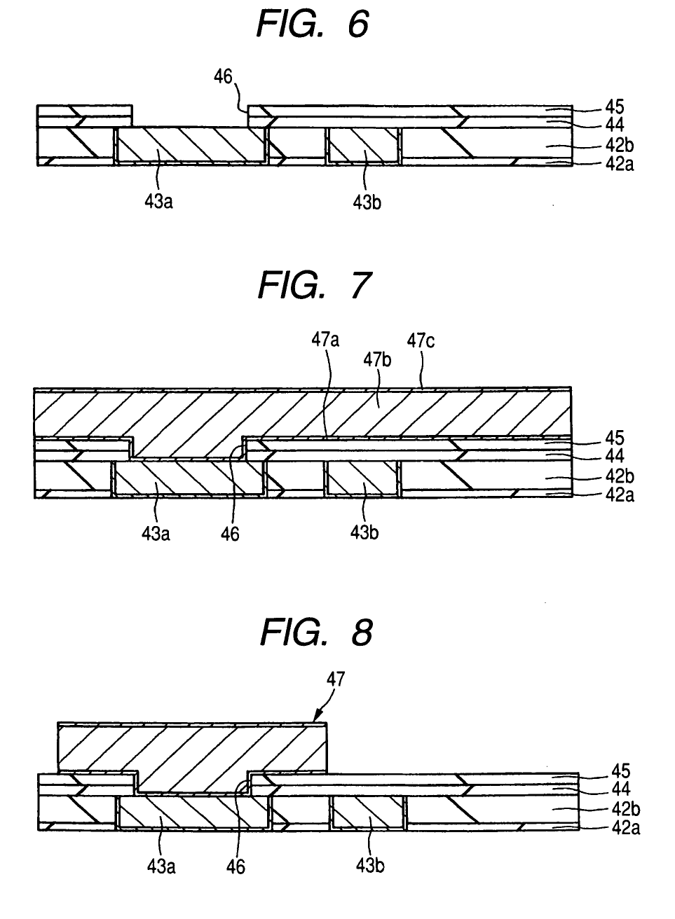

As illustrated in FIG. 7, a titanium/titanium nitride film 47a, an aluminum film 47b and a titanium nitride film 47c are formed successively over the silicon oxide film 45 including the inside of the opening portion 46. The resulting film stack (first conductor film) can be formed, for example, by sputtering. The titanium/titanium nitride film 47a and titanium nitride film 47c function as a barrier metal film and a tantalum film or tantalum nitride film are usable instead.

As illustrated in FIG. 8, the film stack is patterned by photolithography and etching, whereby the buffer layer 47 made of a film stack of the titanium/titanium nitride film 47a, aluminum film 47b and titanium nitride film 47c can be formed.

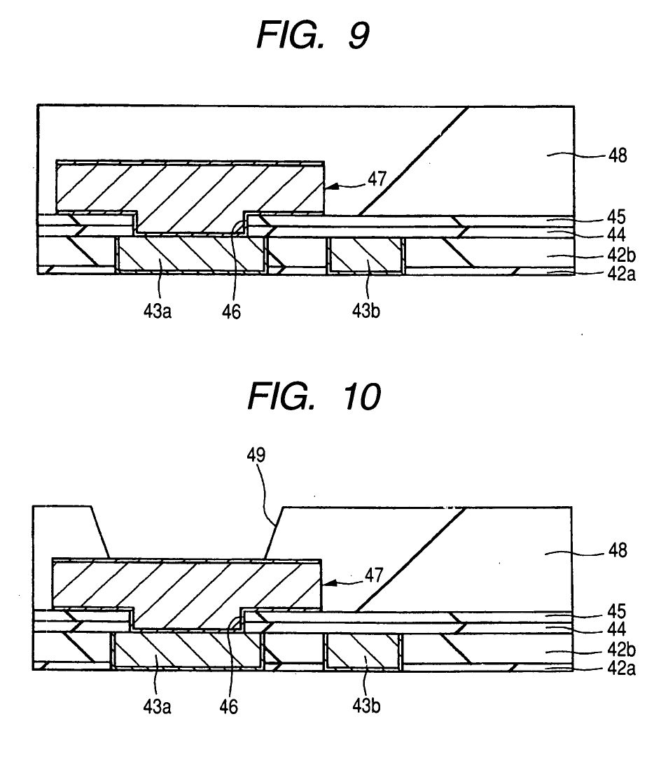

As illustrated in FIG. 9, a polyimide resin film (second insulating film) 48 is formed over the silicon oxide film 45 including the upper surface of the buffer layer 47. The polyimide resin film 48 is patterned using photolithography to form an opening portion (second opening portion) 49 in the polyimide resin film 48 as illustrated in FIG. 10. The surface of the buffer layer 47 is exposed from the bottom of this opening portion 49.

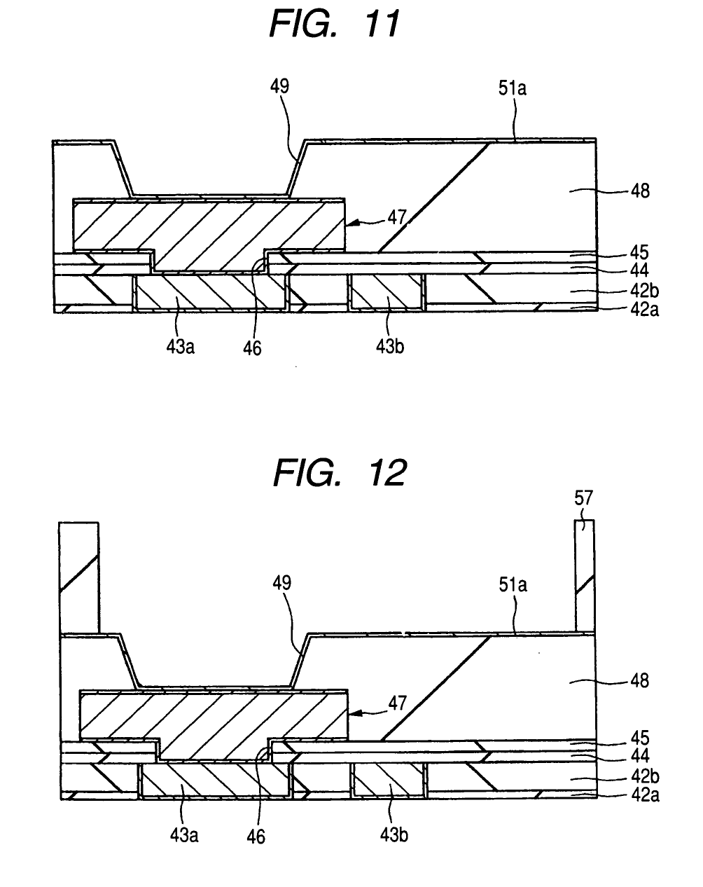

As illustrated in FIG. 11, a seed layer 51a made of a thin copper film is formed over the polyimide resin film 48 having the opening portion 49 formed therein. The seed layer 51a can be formed, for example, by sputtering. After application of a resist film 57 onto the seed layer 51a, the resist film 57 is patterned by exposure and development. The patterning is conducted so as to remove the resist film 57 from the redistribution interconnect formation region as illustrated in FIG. 12.

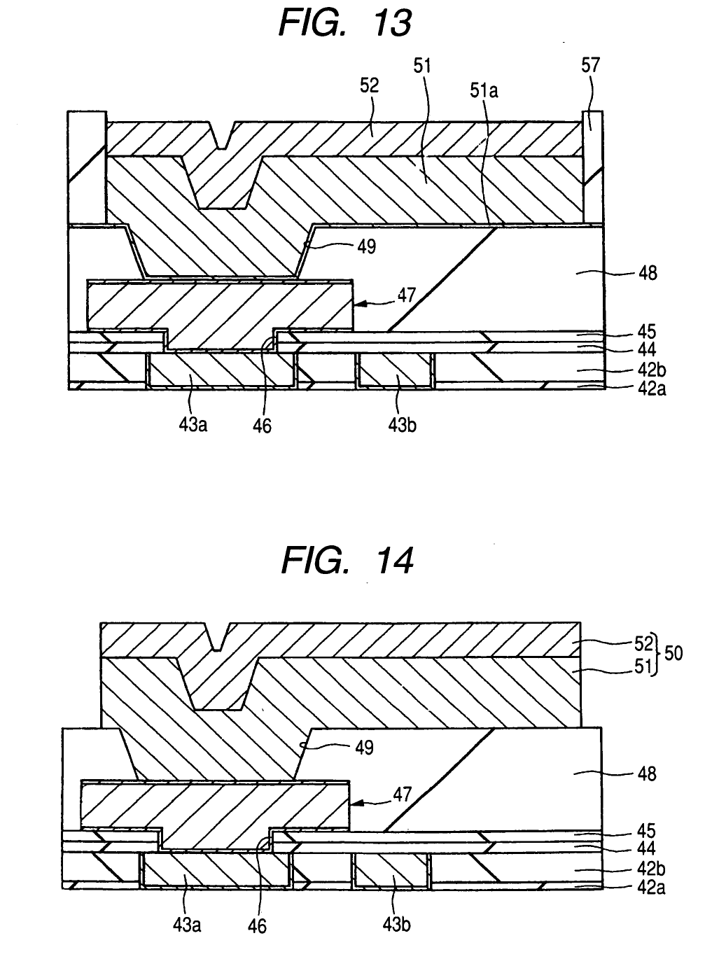

As illustrated in FIG. 13, with the patterned resist film 57 as a mask, a copper film 51 and a nickel film 52 are formed over the seed layer 51a. The copper film 51 and nickel film 52 serve as a second conductor film and can be formed, for example, by electrolytic plating with the seed layer 51a as an electrode. The seed layer 51a is integrated with the copper film 51 so that the seed 51a is not illustrated in the subsequent drawings.

As illustrated in FIG. 14, after removal of the patterned resist film 57, the seed layer 51a is removed by wet etching from a region covered with the resist film 57, whereby a redistribution interconnect 50 made of a film stack of the copper film 51 and nickel film 52 is formed. The nickel film 52 is formed over the copper film 51 for the purpose of preventing the reaction between the copper film 51 and a solder paste 56a to be formed in a bump electrode formation region over the redistribution interconnect 50. When the seed layer 51 is removed from a region covered with the resist film 57, the surface of the redistribution interconnect 50 is etched simultaneously, but this poses no problem because the redistribution interconnect 50 is far thicker than the seed layer 51a.

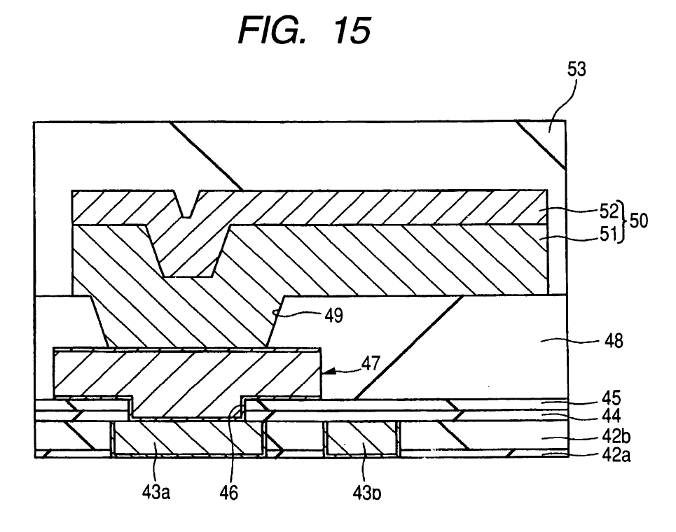

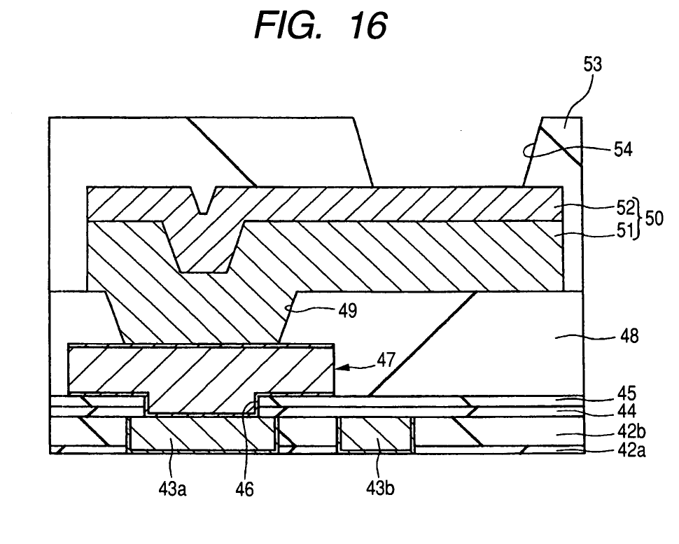

As illustrated in FIG. 15, a polyimide resin film (third insulating film) 53 is formed over the redistribution interconnect 50 made of the copper film 51 and nickel film 52. The polyimide resin film 53 is then subjected to exposure and development, whereby an opening portion (third opening portion) 54 is formed in a bump electrode formation region as illustrated in FIG. 16. From the bottom of this opening portion 54, the redistribution interconnect 50 is exposed.

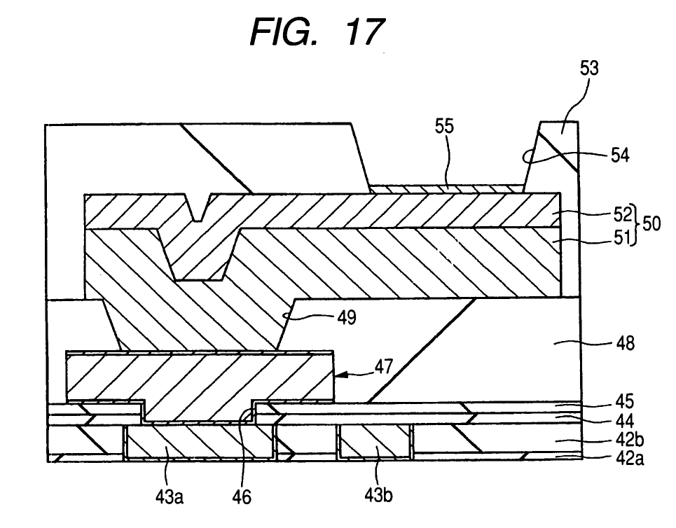

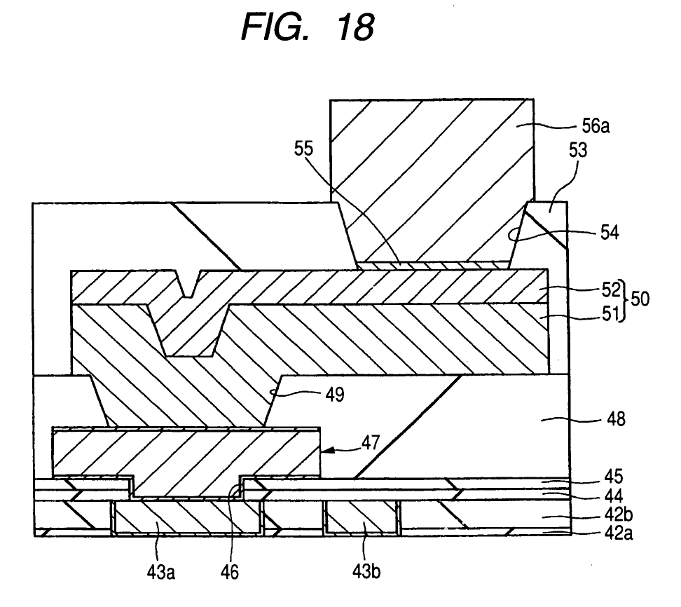

As illustrated in FIG. 17, a gold film 55 is formed by electroless plating over the redistribution interconnect (bump land) 50 exposed from the opening portion 54. As illustrated in FIG. 18, the solder paste 56a is printed on the gold film 55 by solder printing. The solder paste 56a just after printing is printed almost flatly in a region wider than the bump land. By heating the semiconductor substrate 20 to cause reflow (melting and recrystallization) of the solder paste 56a, a hemispheric bump electrode 56 as illustrated in FIG. 4 is formed over the gold film 55. The bump electrode 56 is made of, for example, a lead (Pb)-free solder composed of tin (Sn), silver (Ag) and copper (Cu). The bump electrode 56 may be formed by plating instead of the above-described printing. The bump electrode 56 can also be formed by feeding a solder ball, which has been formed in advance, onto the bump land and then causing reflow of the semiconductor substrate 20. By the redistribution interconnect 50, the space of the bump land formed over the redistribution interconnect 50 is made wider than the space of the uppermost-level interconnect 43a which facilitates the mounting of the bump electrode 56. In such a manner, the semiconductor device of Embodiment 1 can be manufactured.

A reliability test (selection test) in which the semiconductor device thus manufactured is operated in repetition while applying to it a temperature change, for example, between −50° C. to 125° C. is then performed. At this time, a heat load is added to the semiconductor device repeatedly, which causes expansion and contraction of films constituting the semiconductor device. In particular, a contraction stress occurs in the nickel film 52 which is a portion of the redistribution interconnect 50 and the polyimide resin film 48 as illustrated in FIG. 4. Accordingly, the stress is concentrated on a triple point X at which the interfaces of three films, that is, the copper film 51 constituting the redistribution interconnect 50, polyimide film 48 and buffer layer 47 are brought into contact with each other. The buffer layer 47 for absorbing a stress is laid just below the triple point X on which a stress is concentrated so that the stress is relaxed at the interface Y between the silicon nitride film 44 and the silicon oxide film 42b which has the uppermost-level interconnect 43a embedded therein and will be an interlayer insulating film. The peeling at the interface Y can therefore be prevented.

The reliability test is followed by the electrical characteristics test of the semiconductor device. Although there occurs a potential difference between the uppermost-level interconnect 43a and uppermost-level interconnect 43b, drifting of copper between the uppermost-level interconnect 43a and uppermost-level interconnect 43b does not occur because peeling at the interface Y is prevented. Accordingly, a short-circuit fault resulting from the conduction between the uppermost-level interconnect 43a and uppermost-level interconnect 43b does not occur. The semiconductor device thus manufactured has therefore improved reliability.

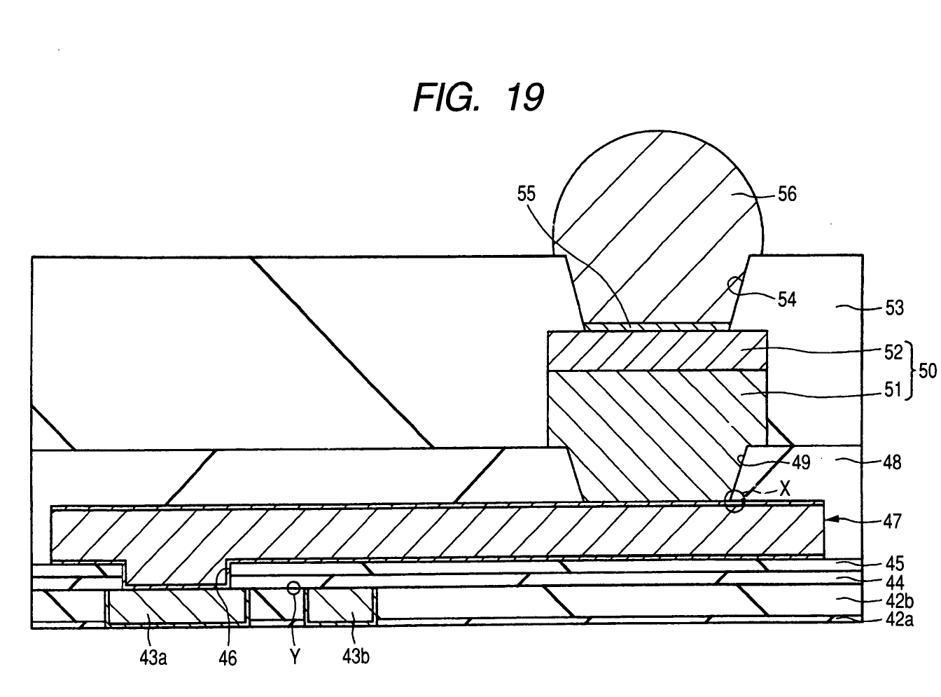

A modification example of the semiconductor device of Embodiment 1 will next be described. FIG. 19 is a cross-sectional view illustrating the modification example of Embodiment 1. In FIG. 19, the modification example is characterized in that the opening portion 46 for connecting the uppermost-level interconnect 43a to the buffer layer 47 and the opening portion 49 for connecting the buffer layer 47 and the redistribution interconnect 50 are formed at two-dimensionally different positions. In Embodiment 1, as illustrated in FIG. 4, the opening portion 49 is formed just above the opening portion 46 via the buffer layer 47 and they are two-dimensionally overlapped with each other. In the modification example, on the other hand, as illustrated in FIG. 19, the opening portion 49 is formed at a position apart from the position just above the opening portion 46. This makes it possible to prevent the peeling of a film at the interface Y because the interface Y can be made apart from the position just below the triple point X on which a stress is concentrated.

The uppermost-level interconnect 43a is formed below the opening portion 46 and another uppermost-level interconnect 43b is formed close to the uppermost-level interconnect 43a. When peeling occurs at the interface Y between the silicon oxide film 42b and silicon nitride film 44 which is present in the vicinity of the opening portion 46, the drifting of copper inevitably causes short-circuit between the uppermost-level interconnect 43a and uppermost-level interconnect 43b. In particular when the buffer layer 47 is not disposed, the redistribution interconnect 50 is formed via the opening portion 46. Then, the interface Y inevitably exists just below the triple point X and peeling at the interface Y tends to occur by a stress. Here, as illustrated in Embodiment 1, by disposing the buffer layer 47, even if the interface Y exists below the triple point X, it is possible to prevent peeling at the interface Y due to a stress relaxing effect and increase of distance between the triple point X and interface Y. Moreover, in the modification example, the buffer layer 47 is extended in the lateral direction of FIG. 19, which enables formation of the opening portion 46 at a position different from that of the opening portion 49. In other words, disposal of the buffer layer 47 enables disposal of the opening portion 49 for connecting the buffer layer 47 to the redistribution interconnect 50 at a position apart from the position just above the opening portion 46 for connecting the uppermost-level interconnect 43a to the buffer layer 47. The triple point X on which a stress is concentrated can therefore be made apart from the interface Y, by which the conduction of a stress to the interface Y can be reduced further, leading to prevention of peeling at the interface Y. Thus, by disposing the buffer layer 47, the connection layout of the uppermost-level interconnect 43a, buffer layer 47 and redistribution interconnect 50 can be changed readily and a layout having a relatively free from a stress on the interface Y can be realized.

### Embodiment 2

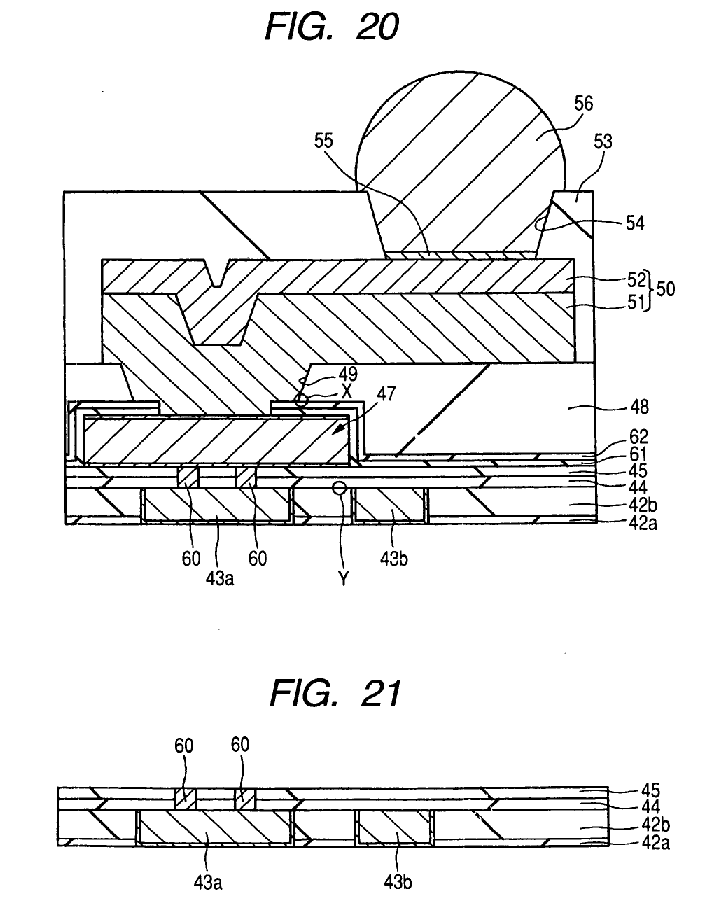

In Embodiment 1, the buffer layer 47 is disposed on the uppermost-level interconnect 43a by using the opening portion 46 as illustrated in FIG. 4. In Embodiment 2, on the other hand, a plug 60 is formed between the uppermost-level interconnect 43a and buffer layer 47 as illustrated in FIG. 20.

FIG. 20 is a cross-sectional view illustrating a portion of the structure of a semiconductor device according to Embodiment 2. From FIG. 20, lower-level interconnects below the uppermost-level interconnects 43a and 43b are omitted. What is different in FIG. 20 from Embodiment 1 is that the device of Embodiment 2 is equipped with the plug 60. In Embodiment 2, the plug 60 is formed over the uppermost-level interconnect 43a and the buffer layer 47 is formed over the plug 60. Such a constitution also makes it possible to prevent the peeling of a film due to the stress at the interface Y, because the buffer layer 47 for relaxing the stress is disposed between the triple point X on which a stress is concentrated and the interface Y. The advantage of the plug 60 is that compared with Embodiment 1 in which the buffer layer 47 is disposed in the opening portion 46 formed over the uppermost-level interconnect 43a, the area of the opening over the uppermost-level interconnect 43a can be decreased. By the decrease in the opening area, the exposure of a copper film constituting the uppermost-level interconnect 43a can be reduced to the minimum necessary during the manufacturing steps. Corrosion on the surface of the copper film can therefore be reduced. The plug 60 is made of, for example, a tungsten film.

The semiconductor device of Embodiment 2 has the below-described structure. The manufacturing method of it will next be described referring to some drawings.

Steps after the formation of the uppermost-level interconnects 43a and 43b will next be described. As illustrated in FIG. 21, over the silicon oxide film 42b having the uppermost-level interconnects 43a and 43b formed therein, a silicon nitride film 44 and a silicon oxide film 45 are formed successively. For the formation of these silicon nitride film 44 and silicon oxide film 45, CVD can be employed for example. A film stack made of the silicon nitride film 44 and silicon oxide film 45 serves as a first insulating film.

A trench penetrating the silicon nitride film 44 and silicon oxide film 45 and reaching the uppermost-level interconnect 43a is formed using photolithography and etching. A tungsten film is formed over the silicon oxide film 45 including the inside of the trench. This tungsten film can be formed using, for example, CVD. The surface of the tungsten film is then polished by, for example, CMP to remove an unnecessary portion of the tungsten film. By this step, the plug 60 is formed by burying the tungsten film in the trench.

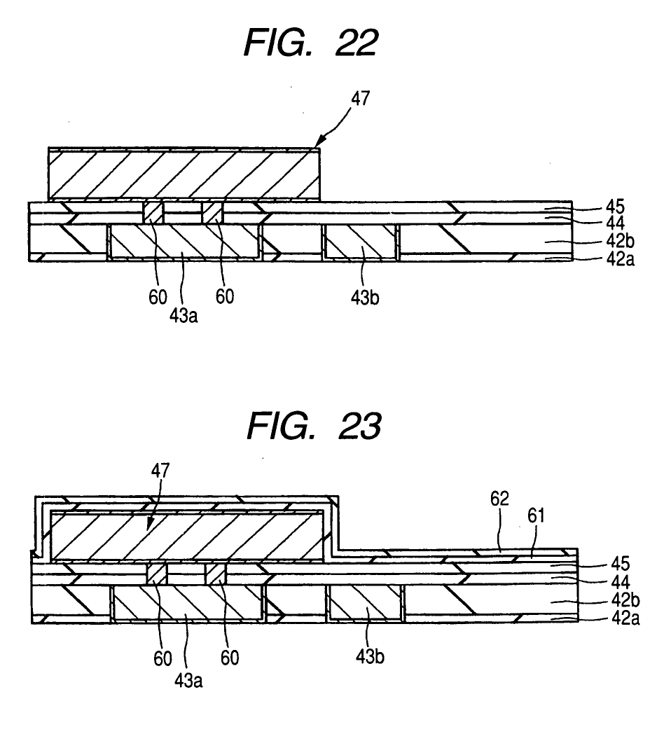

As illustrated in FIG. 22, a buffer layer 47 is formed over the silicon oxide film 45 having the plug 60 formed therein. The buffer layer 47 can be formed by successively depositing a titanium nitride film, an aluminum film and a titanium nitride film to form a film stack (first conductor film) and then patterning the resulting film stack by photolithography and etching. The titanium nitride film and aluminum film can be formed using, for example, sputtering.

As illustrated in FIG. 23, a silicon oxide film 61 and a silicon nitride film 62 are formed over the silicon oxide film 45 having the buffer layer 47 formed thereover. The silicon oxide film 61 and silicon nitride film 62 can be formed using, for example, CVD. The silicon oxide film 61 has a thickness of, for example, about 200 nm, while the silicon nitride film 62 has a thickness of, for example, about 600 nm.

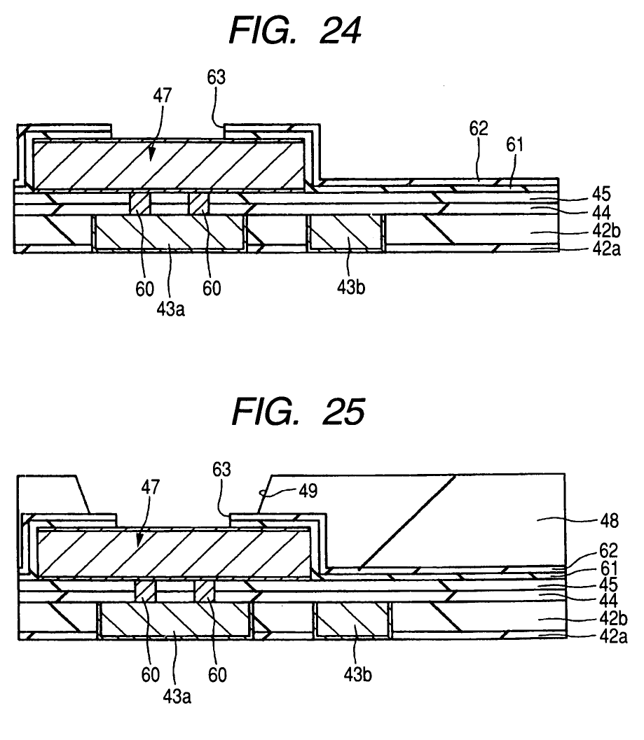

As illustrated in FIG. 24, an opening portion 63 is formed in the silicon oxide film 61 and silicon nitride film 62 using photolithography and etching. The surface of the buffer layer 47 is exposed from the bottom of this opening portion 63.

As illustrated in FIG. 25, a polyimide resin film 48 is formed over the silicon nitride film 62 having the opening portion 63 formed therein. A film stack of the silicon oxide film 61, silicon nitride film 62 and polyimide resin film 48 serves as a second insulating film. An opening portion 49 is then formed in the polyimide resin film 48 by using photolithography. A large opening portion is formed by the opening portion 49 formed in the polyimide resin film 48 and the opening portion 63 formed in the silicon oxide film 61 and silicon nitride film 62. A redistribution interconnect is then formed to embed therewith the opening portions 49 and 63. Steps thereafter are similar to those of Embodiment 1 so that description on them is emitted.

In Embodiment 2, an example of forming an interlayer insulating film between the buffer layer 47 and redistribution interconnect from the film stack of the silicon oxide film 61, silicon nitride film 62 and polyimide resin film 48 was described. The interlayer insulating film may be composed alone of the polyimide resin film 48 without forming the silicon oxide film 61 and silicon nitride film 62.

The present invention was described specifically based on some embodiments of the present invention. It is needless to say that the invention is not limited to or by these embodiments and changes may be made without departing from the scope of the present invention.

The present invention can be used widely in the manufacturing industry of semiconductor devices.

1. A semiconductor device, comprising:
(a) a semiconductor substrate;
(b) an interlayer insulating film formed over the semiconductor substrate;
(c) an uppermost-level interconnect formed so as to bury the interconnect in the interlayer insulating film;
(d) a buffer layer formed over the uppermost-level interconnect;
(e) a redistribution interconnect formed over the buffer layer; and
(f) a bump electrode formed over one end portion of the redistribution interconnect.

2. A semiconductor device according to claim 1, wherein a first insulating film is formed over the interlayer insulating film having the uppermost-level interconnect buried therein and the buffer layer is formed so as to connect to the uppermost-level interconnect exposed from a first opening portion made in the first insulating film.

3. A semiconductor device according to claim 2, wherein a second insulating film is formed over the buffer layer and the redistribution interconnect is formed so as to connect to the buffer layer exposed from a second opening portion made in the second insulating film.

4. A semiconductor device according to claim 3, wherein the buffer layer serves to prevent peeling of the first insulating film from the interlayer insulating film, which peeling occurs owing to a stress generated at the interface between the redistribution interconnect and the second insulating film.

5. A semiconductor device according to claim 3, wherein the width of the buffer layer is greater than that of the uppermost-level interconnect and at the same time, greater than that of the second opening portion.

6. A semiconductor device according to claim 1, wherein a first insulating film is formed over the interlayer insulating film having the uppermost-level interconnect buried therein and the buffer layer is formed over a plug which is disposed in the first insulating film and is connected to the uppermost-level interconnect.

7. A semiconductor device according to claim 3, wherein the first opening portion and the second opening portion are formed at positions two-dimensionally different from each other.

8. A semiconductor device according to claims 3, wherein the second insulating film is made of a polyimide resin film.

9. A semiconductor device according to claim 1, wherein the uppermost-level interconnect is made of a copper film.

10. A semiconductor device according to claim 1, wherein the uppermost-level interconnect is made of an aluminum film or a tungsten film.

11. A semiconductor device according to claim 1, wherein the buffer layer is made of an aluminum film or aluminum alloy film.

12. A semiconductor device according to claim 1, wherein the redistribution interconnect is made of a film stack of a copper film and a nickel film.

13.-20. (canceled)
